(19) United States
(12) Patent Application Publication
(10) Pub. No.: US 2012/0062255 A1
(43) Pub. Date: Mar. 15, 2012

(54) TEST CIRCUIT AND SEMICONDUCTOR INTEGRATED CIRCUIT HAVING THE SAME

(75) Inventors: Naoto SUDO, Kanagawa (JP); Masafumi TOMODA, Kanagawa (JP)

(73) Assignee: Renesas Electronics Corporation

(21) Appl. No.: 13/207,050

(22) Filed: Aug. 10, 2011

(30) Foreign Application Priority Data
Sep. 10, 2010 (JP) 2010-203550

(51) Int. Cl. G01R 31/00

(52) U.S. Cl. 324/750.01

(57) ABSTRACT

A test circuit is capable of easily testing the standby function of an interface block. The test circuit is used for the interface block disposed on a semiconductor integrated circuit which is switched between a standby mode and a non-standby mode and conducting interfacing between the semiconductor integrated circuit and the outside in the non-standby mode, generating a fixed voltage and outputting the same to a corresponding signal line in the standby mode. The test circuit is disposed on the semiconductor integrated circuit and generates a current in accordance with the voltage level of the signal line in the standby mode.

### CROSS-REFERENCE TO RELATED APPLICATION

The disclosure of Japanese Patent Application No. 2010-203550 filed on Sep. 10, 2010 including the specification, drawings and abstract is incorporated herein by reference in its entirety.

### BACKGROUND

The present invention concerns a test circuit suitable to the testing of a standby function of an interface block, and semiconductor integrated circuit having the same.

Reduction of consumption power has been demanded for semiconductor integrated circuits used for portable equipments which use a battery as an electric energy source and for which long time driving is desired for the sake of the convenience, large video equipment and large computers consuming a large amount of energy and involving problems in view of the countermeasure to the global warming due to CO₂ emission and saving for energy cost.

A standby function is one of known techniques to reduce power consumption. The standby function is a technique of enabling to reduce the power consumption by disconnecting the supply of electric power for a certain period to a portion of equipment, particularly, some semiconductor integrated circuits or a portion of the semiconductor circuits which are not necessary to function continuously.

Simple disconnection of the semiconductor integrated circuit from the power supply means destruction of the operation state so far, and makes it difficult to recover the original state from the operation state on the way when the power supply is disconnected by supplying the power again. Further, at the boundary between a portion where the power supply is disconnected and a portion that continues the stationary operation, an intermediate voltage is inputted to transistors as constituent elements of the semiconductor integrated circuit to generate a through current. This result brings in a problem of increase in the power consumption, malfunction, abnormality and degradation of devices. An interface block having the standby function has been known as a technique for solving such problems.

The interface block is a circuit disposed to the semiconductor integrated circuit for the function of connecting the outside and the inside of the semiconductor integrated circuit, which enables transmission of signals between semiconductor integrated circuits of difference characteristics such as operation power source voltage. For example, a level shifter is used as the interface block.

In addition to the inherent function described above, the interface block having the standby function has a function of outputting a fixed voltage at a Low level or a High level instead of an intermediate voltage or an uncertain voltage to a random logic inside the semiconductor integrated circuit or to the outside for avoiding the input of the intermediate voltage or the uncertain voltage to a transistor disposed in the semiconductor integrated circuit or for suppressing the power consumption of the interface block per se in the standby mode of the semiconductor integrated circuit (mode in which the interface between the semiconductor integrated circuit and the outside is interrupted).

FIG. 12 shows a block diagram of a low power consumption SRAM provided with an interface block having a standby function (I/O Terminal in Standby State of Low Power Consumption SRAM [online] [Search on Mar. 25, 2010] Renesas Electronics Corporation, internet <URL:http://www.necel.com/faq/ja/f_usram.html#0401>: Non-patent document 1). Further, FIG. 13 shows the operation mode of the low power consumption SRAM shown in FIG. 12. Only the portion relevant to the present invention is to be described. The circuit shown in FIG. 12 has input buffers (interface blocks) I11 and I12. A signal line E11 is connected to the input terminal of the input buffer I11, and an input signal is mainly inputted from the outside. A signal line S01 is connected to the control terminal of the input buffer I11, and an I/O input buffer control signal (mode switch signal) is inputted. The output terminal of the input buffer I11 is connected to a signal line S11 and outputs an output signal to a random logic in the subsequent stage. A signal line E12 is connected to the input terminal of the input buffer I12, and an input signal is mainly inputted from the outside. A signal line S02 is connected to the control terminal of the input buffer I12, and an I/O input buffer control signal is inputted. The output terminal of the input the I12 is connected to a signal line S12 and outputs an output signal to the random logic at the subsequent stage.

The input buffers I11 and I12 fix the voltage level of the signal lines S11 and S12 to a Low level irrespective of the voltage level of the signal lines E11 and E12 (HiZ, High level, Low level) when the I/O input buffer control signal is at a Low level. That is, the input buffers I11 and I12 output a fixed voltage at the Low level to the random logic in the subsequent stage irrespective of the voltage level of the input signal when the I/O input buffer control signal is at the Low level.

As described above, requirement for testing the standby function of the interface block has been increased along with increase of semiconductor integrated circuits mounted with the interface block having the standby function. In other words, a requirement of testing whether the interface block having the standby function outputs a desired fixed voltage in the standby mode or not has been increased.

### SUMMARY

The interface block having the standby function is applied for maximizing the effect of reducing the power consumption, as a rule, to all digital signal lines interfacing the semiconductor integrated circuit and the outside. Then, in the standby mode, fixed voltages are outputted from all of the interface blocks to corresponding signal lines. In other words, in the standby mode, the interface between the semiconductor integrated circuit and the outside is interrupted in all of the interface blocks. Therefore, there was a problem that the result of output of the interface blocks in the standby mode cannot be outputted to the outside and observed. That is, there was a problem that even when the standby function of any one of the interface blocks has defect, there is no method to detect the defect and products having defect flow out in the market.

Further, it may be considered to test the standby function of the interface block by observing the state where the semiconductor integrated circuit returns from the standby mode. However, since such a test requires an enormous amount of test vectors, it is actually impossible to perform the test by using a tester that handles a limited amount of test vectors.

In addition, it may also be considered to perform the test by newly adding an external terminal used exclusively for the test to the semiconductor integrated circuit. However, this brings in a problem of increasing the chip size or changing the substrate design due to increase in the number of external terminal. It is particularly difficult to take such a countermeasure for portable type equipment having less mounting area.

As described above, the related art involves a problem that the standby function of the interface block cannot be tested easily.

The test circuit according to an aspect of the invention is a test circuit for an interface block disposed on a semiconductor integrated circuit switched between a standby mode and a non-standby mode interfacing the semiconductor integrated circuit and the outside in a non-standby mode, and generating a fixed voltage and outputting the same to a corresponding signal line in the standby mode. The test circuit is disposed on the semiconductor integrated circuit and generates a current in accordance with the voltage level of the signal line in the standby mode.

According to the circuit structure described above, the standby function of the interface block can be tested easily.

The present invention can provide a test circuit capable of easily testing the standby function of the interface block.

### BRIEF DESCRIPTION OF THE DRAWINGS

FIG. 1 is a view showing a semiconductor integrated circuit having a test circuit according to a first embodiment of the invention;

FIG. 2 is a view showing an example of a circuit structure of a standby test circuit C0;

FIG. 3 is a truth table for the standby test circuit C0;

FIG. 4 is a view showing a semiconductor integrated circuit having the test circuit according to a second embodiment of the invention;

FIG. 5 is a view showing a semiconductor integrated circuit in a related art;

FIG. 6 is a truth table of an interface block I0;

FIG. 7 is a truth table of an interface block I1;

FIG. 8 is a truth table of an interface block I2;

FIG. 9 is a truth table of an interface block I3;

FIG. 10 is a truth table of an interface block I4;

FIG. 11 is a timing chart showing the operation of the semiconductor integrated circuit shown in FIG. 5;

FIG. 12 is a view showing a low power consumption SRAM in the related art; and

FIG. 13 is a chart showing the operation mode of the low power consumption SRAM in the related art.

### DETAILED DESCRIPTION

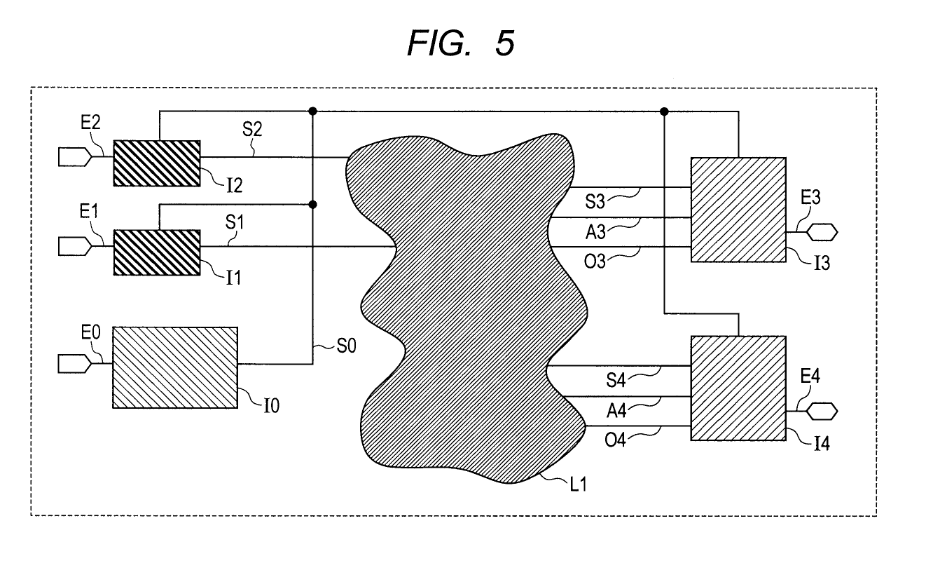

Before explaining a semiconductor integrated circuit having a test circuit according to this embodiment, a semiconductor integrated circuit not having the test circuit is to be described with reference to FIGS. 5 to 10 for comparison.

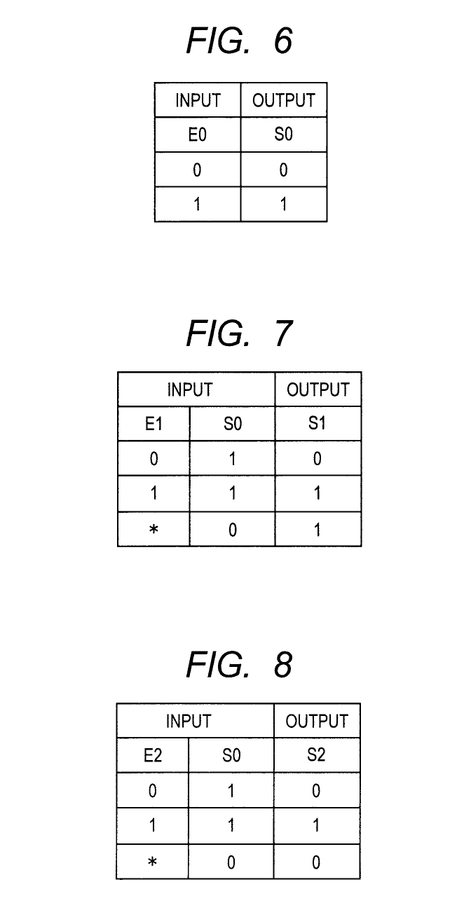

FIG. 5 is a view showing a usual semiconductor integrated circuit provided with an interface block having a standby function. FIGS. 6 to 10 are truth tables of interface blocks I0 to I4. In the truth tables shown in FIGS. 6 to 10, “0” shows a Low level, “1” shows a High level, and “*” shows a Low level or a High level. Further, the standby mode is a mode where the interface between the semiconductor integrated circuit and the outside is interrupted, while the non-standby mode is a converse mode where the interface between the semiconductor integrated circuit and the outside is not interrupted.

The semiconductor integrated circuit shown in FIG. 5 has a random logic L1 and the interface blocks I0 to I4. While the interface blocks I1 to I4 have the standby function, the interface block I0 has no standby function. That is, the interface block I0 and interface blocks I1 to I4 have functions different from each other. Description is to be made specifically. In the following description, references attached to respective signal lines are attached also to corresponding signals for the sake of convenience.

The interface block I0 has a function of controlling the standby state of the interface blocks I1 to I4 and is mounted to a semiconductor integrated circuit. An external signal line E0 is connected to the input terminal of the interface block I0, and a mode switching signal E0 is inputted from the outside. The output terminal of the interface block I0 is connected by way of an internal signal line S0 to control terminals of the interface blocks I1 to I4 and outputs a control signal S0 in accordance with the mode switching signal E0. As shown in the truth table of FIG. 6, when the mode switching signal E0 is, for example, at a Low level, the control signal S0 shows a Low level. When the mode switching signal E0 is at a High level, the control signal S0 shows a High level. When the mode switching signal E0 is at the Low level, that is, the control signal S0 is at the Low level a standby mode is attained and, when the mode switching signal E0 is at a High level, that is, the control signal S0 is at a High level, the non-standby mode is attained.

The interface block I1 is an interface block having a standby function for external input. An external signal line E1 is connected to the input terminal of the interface block I1, and an input signal E1 is inputted from the outside. The output terminal of the interface block I1 is connected by way of an internal signal line S1 to the random logic L1 which is a circuit for realizing the function of the semiconductor integrated circuit per se and outputs an output signal S1 in accordance with the input signal E1. As shown in the truth table in FIG. 7, when the mode is in the non-standby mode (control signal S0 is at a High level) and the input signal E1 is at a Low level, for example, the output signal S1 shows a Low level. When the mode is in the non-standby mode and the input signal E1 is at a High level, the output signal S1 shows a High level. On the other hand, in the standby mode (control signal S0 is at a Low level), the output signal S1 shows a High level irrespective of the voltage level of the input signal E1. That is, the interface block I1 outputs a fixed voltage (S1) at a High level in the standby mode.

The interface block I2 is an interface block having a standby function for external input. An external signal line E2 is connected to the input terminal of the interface block I2, and an input signal E2 is inputted from the outside. The output terminal of the interface block I2 is connected by way of an internal signal line S2 to the random logic L1 and outputs an output signal S2 in accordance with the input signal E2. As shown in the truth table in FIG. 8, when the mode is in the non-standby mode (control signal S0 is at a High level) and the input signal E2 is at a Low level, for example, an output signal S2 shows a Low level. When the mode is in the non-standby mode and the input signal E2 is at a High level, the output signal S2 shows a High level. On the other hand, in the standby mode (control signal S0 is at a Low level), the output signal S2 shows a Low level irrespective of the voltage level of the input signal E2. That is, the interface block I2 outputs a fixed voltage (S2) at the Low level in the standby mode.

The interface block I3 is a bidirectional interface block having a standby function. An external signal line E3 is connected to the bidirectional terminal of the interface I3. The random logic L1 is connected by way of an internal signal line A3 to the input terminal of the interface block I3 and an input signal A3 from the random logic L1 is inputted. The output terminal of the interface block I3 is connected by way of an internal signal line S3 to the random logic L1, and outputs an output signal S3, for example, in accordance with the bidirectional signal E3 for external input. The input/output switching terminal of the interface block I3 is connected by way of an internal signal line O3 to the random logic L1, and inputted with an input/output switching signal O3 from the random logic L1.

Whether the interface block I3 is used for external input or external output is decided based on the input/output switching signal O3. For example, the interface block I3 is used for external output when the input/output switching signal O3 is at a High level and used for external input when the input/output switching signal O3 is at a Low level.

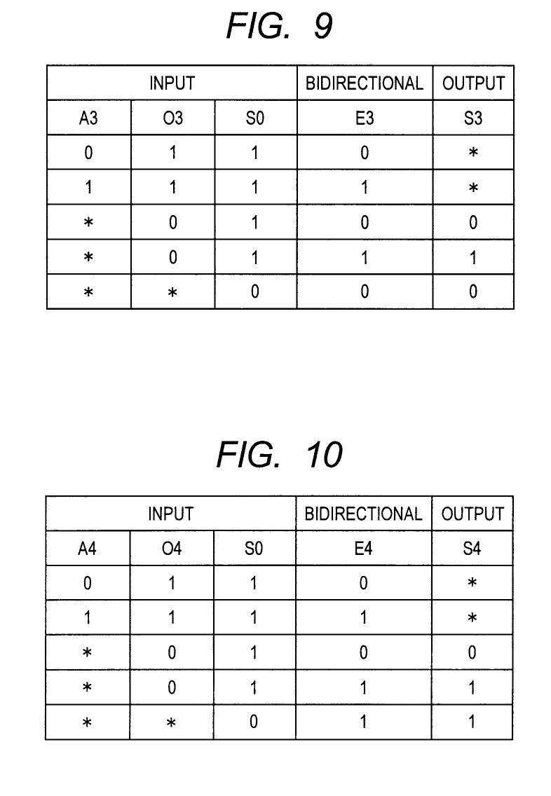

As shown in the truth table in FIG. 9, when the mode is in the non-standby mode (control signal S0 at a High level) and the input/output switching signal O3 is at a High level, for example, the bidirectional signal E3 for external output shows a Low level when the input signal A3 is at a Low level, and the bidirectional signal E3 for external output shows a High level when the input signal A3 is at a High level. When the mode is in the non-standby mode (control signal S0 is at a High level) and the input/output switching signal O3 is at a Low level, the output signal S3 shows a Low level when the bidirectional signal E3 for external input is at the Low level, and the output signal S3 shows a High level when the bidirectional signal E3 for external input is at the High level. On the other hand, in the standby mode (control signal S0 is at a Low level), the output signal S3 shows the Low level irrespective of the voltage level of the bidirectional signal E3, the input/output switching signal O3, and the input signal A3. That is, the interface block I3 outputs a fixed voltage (S3) at the Low level in the standby mode.

An interface block I4 is a bidirectional interface block having a standby function. An external signal line E4 is connected to the bidirectional terminal of the interface 14. The random logic L1 is connected by way of an internal signal line A4 to the input terminal of the interface block I4, and an input signal A4 from the random logic L1 is inputted. The output terminal of the interface block I4 is connected by way of an internal signal line S4 to the random logic L1, and outputs an output signal S4, for example, in accordance with the bidirectional signal E4 for external input. The random logic L1 is connected by way of an internal signal line O4 to the input/output switching terminal of the interface block I4, and inputted with an input/output switching signal O4 from the random logic L1.

Whether the interface block I4 is used for external input or external output is decided based on the input/output switching signal O4. For example, the interface block I4 is used for external output when the input/output switching signal O4 is at a High level and used for external input when the input/output switching signal O4 is at a Low level.

As shown in the truth table in FIG. 10, when the mode is in the non-standby mode (control signal S0 at a High level) and the input/output switching signal O4 is at a High level for example, the bidirectional signal E4 for external output shows a Low level when the input signal A4 is at a Low level, and the bidirectional signal E4 for external output shows a High level when the input signal A4 is at a High level. When the mode is in the non-standby mode (control signal S0 is at a High level) and the input/output switching signal O4 is at a Low level, the output signal S4 shows a Low level when the bidirectional signal E4 for external input is at the Low level, and the output signal S4 shows a High level when the bidirectional signal E4 for external input is at the High level. On the other hand, in the standby mode (control signal S0 is at a Low level), the output signal S4 shows a High level irrespective of the voltage level of the bidirectional signal E4, the input/output switching signal O4, and the input signal A4. That is, the interface block I4 outputs a fixed voltage (S4) at a Low level in the standby mode.

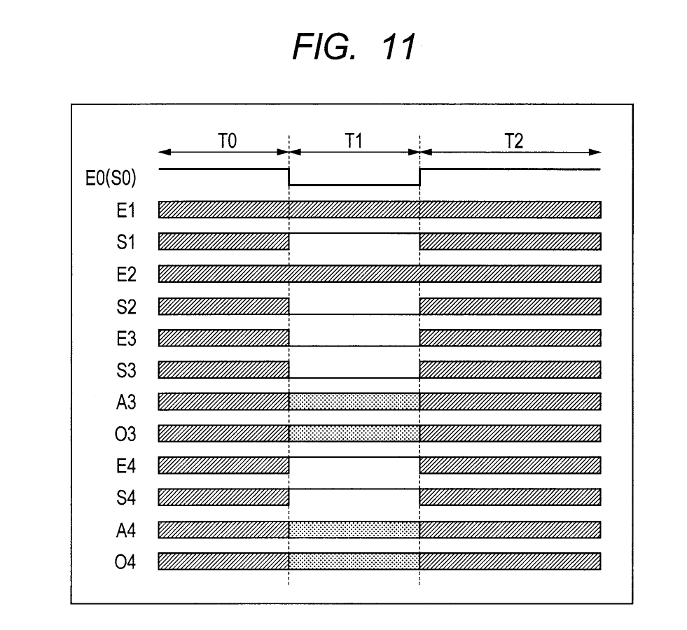

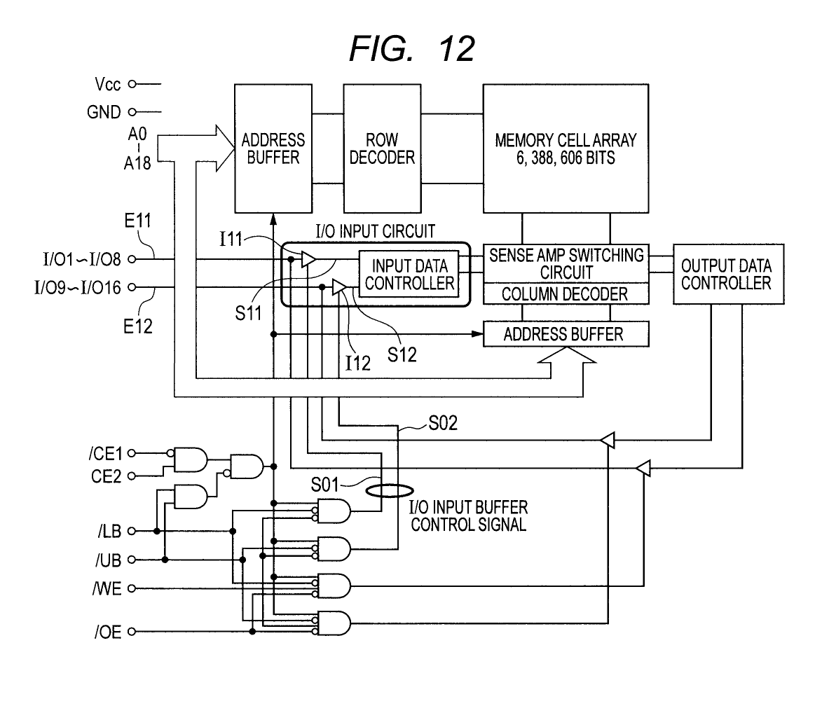

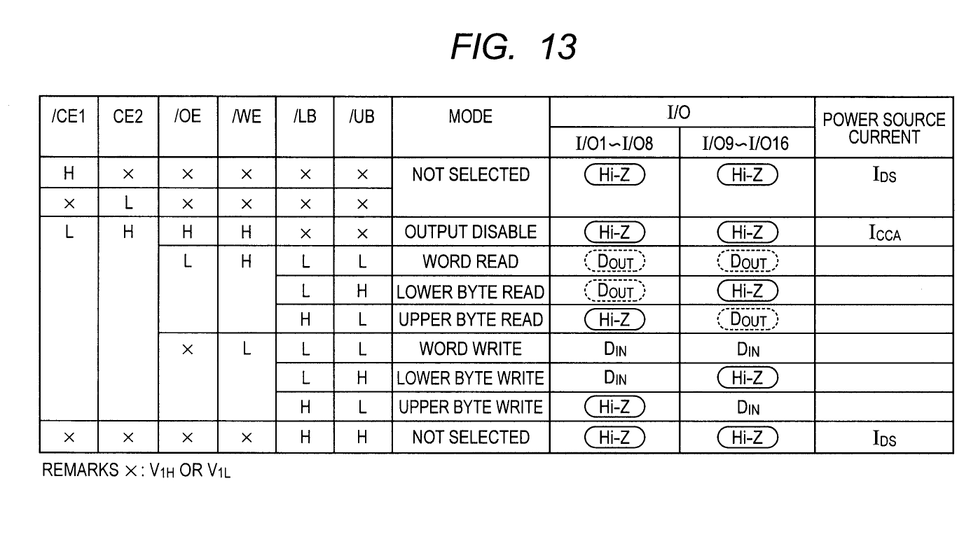

FIG. 11 is a timing chart showing the operation of the circuit shown in FIG. 5. Period T0 and T2 show the non-standby mode period, and period T1 shows the standby mode period. As shown in FIG. 11, in the periods T0 and T2 where the mode switching signal E0 shows a High level, the output signals of the interface blocks I1 to I4 show arbitrary voltage levels in accordance with the external input signals and the signals from the random logic L1.

On the other hand, in the period T1 where the mode switching signal E0 shows a Low level, since the power source supply to the random logic L1 is sometimes interrupted in the actual operation, signals A3, A4, O3, and O4 from the random logic L1 show intermediate voltages. Also in such a case, since the standby function is effective in the interface blocks I3 and I4 receiving such signals, no through current is generated to the input of the intermediate voltages.

Further, even when the external input signals (E1 to E4) are at any voltage level including an intermediate voltage, since the standby function is effective in the interface blocks I1 to I4, the output signals S1 and S4 show High levels and the output signals S2 and S3 show Low levels. That is, the interface blocks I1 to I4 output predetermined fixed voltages (S1 to S4) in the standby mode.

As described above, the interface block is applied to all of the signal lines that perform interface relative to the outside in the circuit shown in FIG. 5. Accordingly, as described above, it is difficult to test the standby function of the interface block easily as they are.

Preferred embodiments of the invention are to be described with reference to the drawings. While the drawings are schematic, the technical scope of the invention should not be construed narrower on the basis of the description of the drawings. Identical elements carry the same references for which duplicate description is to be omitted.

### First Embodiment

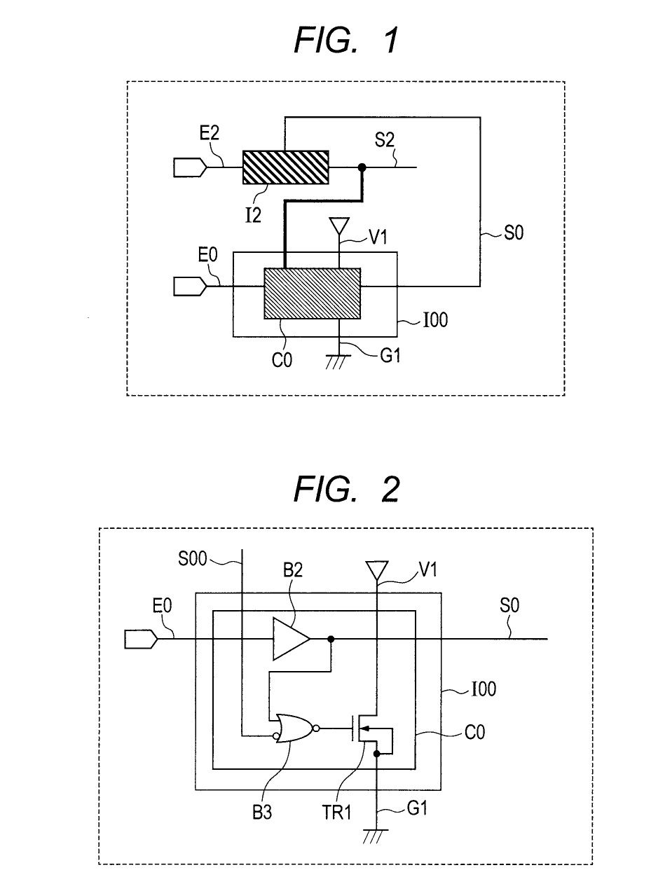

FIG. 1 is a view showing a semiconductor integrated circuit having a standby test circuit (test circuit) C0 according to the first embodiment of the invention. The semiconductor integrated circuit shown in FIG. 1 has a random logic L1 (not illustrated), an interface block I00, and an interface block I2. The interface block I00 has a standby test circuit C0.

The interface block I2 has a standby function but the interface block I00 has no standby function. That is, the interface block I2 and the interface block I00 have functions different from each other. Description is to be made specifically. In the following description, references attached to respective signal lines are attached also to corresponding signals for the sake of convenience.

The interface block I00 has a function of controlling the standby state of the interface block I2 and is mounted to the semiconductor integrated circuit. An external signal line E0 is connected to the input terminal of the interface block I00, and a mode switching signal E0 is inputted from the outside.

The output terminal of the interface block I00 is connected by way of an internal signal line S0 to the control terminal of the interface block I2 and outputs a control signal S0 in accordance with the mode switching signal E0. As shown in the truth table in FIG. 6, when the mode switching signal E0 is, for example, at a Low level, the control signal S0 shows a Low level. When the mode switching signal E0 is at a High level, the control signal S0 shows a High level. In this embodiment, when the mode switching signal E0 is at the Low level, that is, the control signal S0 is at the Low level, the standby mode is attained. When the mode switching signal E0 is at a High level, that is, the control signal S0 is at the High level, the non-standby mode is attained.

The output terminal of the interface block I2 is connected by way of an internal signal line S2 to the input terminal for the detection result of the interface block I00 and inputted with the output signal S2 of the interface block I2. A power supply voltage V1 is supplied to the power supply terminal on the high potential side of the interface block I00. A ground voltage G1 is supplied to the power supply terminal on the low potential side of the interface block I00. While the power supply voltage V1 and the ground voltage G1 are supplied also to the interface block I2, they are not illustrated. Further, while the interface block I00 also has a control circuit for controlling the interface block I2 in addition to the standby test circuit C0, it is not illustrated.

As has been described already with reference to FIG. 8, in the interface block I2, the output signal S2 shows the Low level when the mode is in the non-standby mode and the input signal E2 is at the Low level. When the mode is in the non-standby mode and the input signal E2 is at the High level the output signal S2 shows a High level. On the other hand, in the standby mode, the output signal S2 shows the Low level irrespective of the voltage level of the input signal E2. That is, the interface block I2 outputs a fixed voltage (S2) at the Low level to the random logic L1 (not illustrated) in the standby mode.

FIG. 2 is a view showing an example of a circuit structure of the standby test circuit C0. The standby test circuit C0 shown in FIG. 2 has a level shifter B2, a negative OR circuit (hereinafter simply referred to as an NOR circuit) B3 and a transistor TR1. In this embodiment, description is to be made to an example where the transistor TR1 is an N channel MOS transistor.

The level shifter B2 converts the voltage level of the mode switching signal E0 to a voltage level for the inside of the semiconductor integrated circuit and outputs the same as a control signal S0. The NOR circuit B3 outputs a negative OR for the voltage level of the control signal S0 (that is, voltage level in accordance with the mode switching signal E0) and the inverted value of the voltage level of the internal signal S00. In this embodiment, the output signal S2 of the interface block I2 is transmitted as it is to the internal signal S00.

In the transistor TR1, a power supply voltage V1 is supplied to the drain, a ground voltage G1 is supplied to the source, and an output signal of the NOR circuit B3 is supplied to the gate. Accordingly, when the output signal of the NOR circuit B3 is, for example, at a High level, the transistor TR1 is turned ON and a predetermined current (ON current) flows between the source and the drain of the transistor TR1. On the other hand, when the output signal of the NOR circuit B3 is at a Low level, the transistor TR1 is turned OFF, and a current scarcely flows between the source and the drain of the transistor TR1 (OFF current).

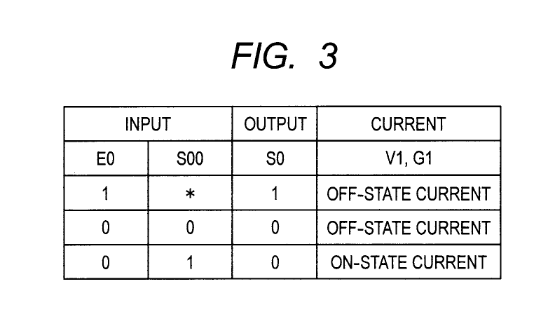

FIG. 3 is a truth table of the standby test circuit C0. In the truth table shown in FIG. 3, “0” shows a Low level, “1” shows a High level, and “*” shows a Low level or a High level.

As shown in the truth table in FIG. 3, in the non-standby mode (control signal S0 is at a High level), the output voltage of the NOR circuit B3 shows a Low level irrespective of the voltage level of the internal signal S00. Accordingly, Off current flows in the transistor TR1. On the other hand, in the standby mode (control signal S0 is at a Low level), the internal signal S00 shows a Low level when the standby function of the interface block I2 is normal, and the internal signal S00 shows a High level when the standby function of the interface block I2 includes defect. That is, when the standby function of the interface block I2 is normal, the output voltage of the NOR circuit B3 shows a Low level in the standby mode. Accordingly, an OFF-current flows in the transistor TR1. Further, when the standby function of the interface block includes defect, the output voltage of the NOR circuit B3 shows a High level in the standby mode. Accordingly, ON current flows in the transistor TR1.

As described above, the standby test circuit C0 according to this embodiment generates a current in accordance with the output voltage of the interface block having the standby function. By measuring the current value, it can be confirmed whether the interface block having the standby function outputs a desired fixed voltage or not in the standby mode. That is, the standby test circuit C0 according to this embodiment can easily test the standby function of the interface block.

In this embodiment, while description has been made to an example where the interface block I2 outputs the fixed voltage (S2) at the Low level in the standby mode, this is not limitative. For example, this embodiment can be changed appropriately, for example, also to a circuit structure in which the interface block I2 outputs a fixed voltage (S2) at a High level in the standby mode for example. In this case, the output signal S2 of the interface block I2 is inverted and transmitted to the internal signal S00.

### Second Embodiment

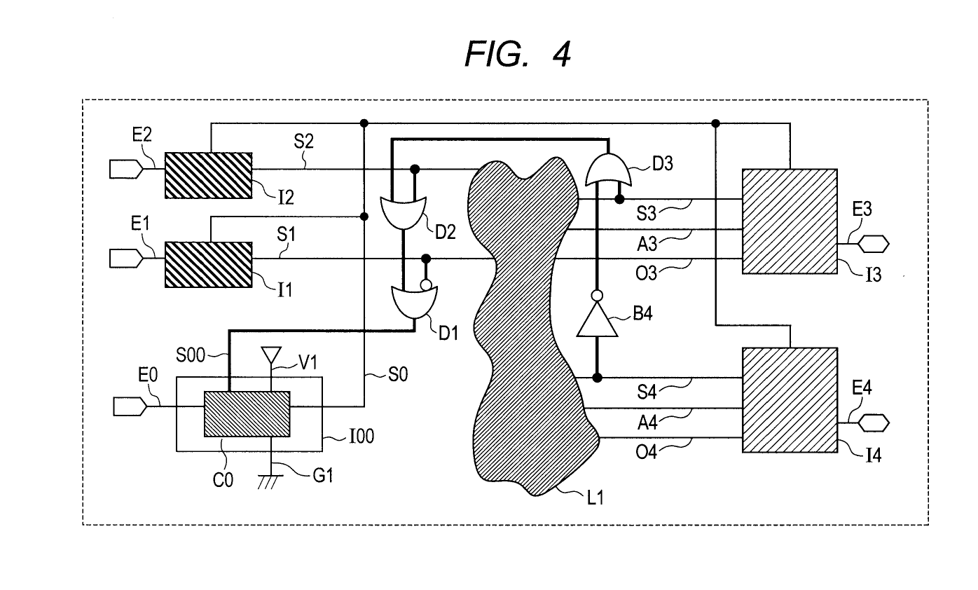

FIG. 4 shows a semiconductor integrated circuit having a standby test circuit (test circuit) C0 according to the second embodiment of the invention. When compared with the semiconductor integrated circuit shown in FIG. 5, the semiconductor integrated circuit shown in FIG. 4 has an interface block I00 instead of the interface block I0 and further has logic OR circuits (hereinafter simply referred to as OR circuits) D1 to D3, and an inverter B4. The standby test circuit C0 according to this embodiment has a feature capable of easily testing the standby function of multiple interface blocks.

The inverter B4 outputs an inverted signal of the output signal S4 of the interface block I4. The OR circuit D3 outputs OR for the output signal S3 of the interface block I3 and the output signal of the inverter B4. The OR circuit D2 outputs OR for the output signal S2 of the interface block I2 and the output signal of the OR circuit D3. The OR circuit D1 outputs OR for the inverted value of the output signal S1 of the interface block I1 and the output signal of the OR circuit D2. The output signal of the OR circuit D1 is transmitted to the internal signal S00. As described above, voltage levels in accordance with the output signals S1 to S4 of the interface blocks I1 to I4 are transmitted to the internal signal S00. Since other circuit structures of FIG. 4 are identical with those in FIG. 5, description therefor is to be omitted.

As has been described already with reference to FIG. 7, the interface block I1 outputs the fixed voltage (S1) at the High level in the standby mode. As has been described already with reference to FIG. 8, the interface block I2 outputs the fixed voltage (S2) at the Low level in the standby mode. As has been described already with reference to FIG. 9, the interface block I3 outputs the fixed voltage (S3) at the Low level in the standby mode. As has been described already with reference to FIG. 10, the interface block I4 outputs the fixed voltage (S4) at the High level in the standby mode.

For example, when the standby function of the interface block I4 includes defect, the output signal S4 of the interface block I4 shows a Low level in the standby mode. In this case, the internal signal S00 shows a High level irrespective of the voltage levels of the output signals S1 to S3 of the interface blocks I1 to I3. This is also identical when the standby function of other interface blocks I1 to I3 includes defect.

That is, when any of the standby function of any of the interface blocks I1 to I4 is normal, the internal signal S00 shows the Low level in the standby mode. On the other hand, when the standby function of any one of the interface blocks I1 to I4 includes defect, the internal signal S00 shows a High level in the standby mode. Since the operation of the standby test circuit C0 is identical with that of the first embodiment, description therefor is to be omitted. Thus, when the standby function of any one of the interface blocks I1 to I4 includes defect, ON current flows to the transistor TR1 in the standby mode and OFF current flows to the transistor TR1 in other case than described above.

As described above, the standby test circuit C0 according to this embodiment generates a current in accordance with the output voltages of multiple interface blocks having the standby function. By measuring the current value, it can be confirmed whether the interface block having the standby function outputs a desired fixed voltage or not in the standby mode. That is, the standby test circuit C0 according to this embodiment can easily test the standby function of the plural interface blocks. Further, since the standby function of the interface blocks I1 to I4 can be tested by using a single standby test circuit C0, increase in the area can be suppressed.

Further, when the standby function of the interface blocks I1 to I4 includes no defect, since only the OFF current flows in the transistor TR1 in the standby mode, the function and the performance of the semiconductor integrated circuit are not hindered.

Further, since only the OFF current flows in the transistor TR1 in the non-standby mode, the function and the performance of the semiconductor integrated circuit are not hindered.

The present invention is not restricted to the first and second embodiments described above but can be modified appropriately within a range not departing from the gist of the invention. For example, while description has been made in the second embodiment to an example in which the internal signal lines S1 to S4 and the internal signal line S00 are connected by way of the NOR circuits D1 to D3 and the inverter B4, this is not limitative. This can be modified appropriately to logically equivalent circuit structures by using other logic circuits (AND circuit, etc.).

Further, while description has been made in the first and second embodiments to an example in which the transistor TR1 is the N-channel MOS transistor, it may be a P-channel MOS transistor. In this case, an OR circuit is used, for example, instead of the NOR circuit B3.

What is claimed is:

1. A test circuit for an interface block disposed on a semiconductor integrated circuit which is switched between a standby mode and a non-standby mode and conducting interfacing between the semiconductor integrated circuit and the outside in a non-standby mode and generating a fixed voltage and outputting the same to a corresponding signal line in the standby mode,
wherein the test circuit is disposed on the semiconductor integrated circuit and generates a current in accordance with a voltage level of the signal line in the standby mode.

2. The test circuit according to claim 1, wherein the circuit has a transistor in which a current flowing between the source and the drain is controlled based on the voltage level of the signal line in the standby mode.

3. The test circuit according to claim 2, wherein the current of the transistor flowing between the source and the drain is controlled based on a voltage level of a mode switching signal given from an outside and a voltage level of the signal line.

4. The test circuit according to claim 1, wherein a plurality of the interface blocks are disposed in the semiconductor integrated circuit, and a current is generated in accordance with the voltages of a plurality of the signal lines corresponding to the interface blocks.

5. The test circuit according to claim 4, the circuit has a transistor in which a current flowing between the source and the drain is controlled based on the voltage levels of the plurality of the signal lines in the standby mode.

6. The test circuit according to claim 5, wherein the current of the transistor flowing between the source and the drain is controlled based on the voltage level of the mode switching signal given from the outside and the voltage levels of the plurality of signal lines.

7. A semiconductor integrated circuit switched between a standby mode and a non-standby mode and having an interface block that conducts interfacing relative to the outside in the non-standby mode and generates a fixed voltage and outputs the same to a corresponding signal line in the standby mode, and a test circuit for generating a current in accordance with the voltage level of the signal line.

8. The semiconductor integrated circuit according to claim 7, wherein the test circuit has a transistor in which a current flowing between the source and the drain is controlled based on the voltage level of the signal line in the standby mode.

9. The semiconductor integrated circuit according to claim 8, wherein the current of the transistor flowing between the source and drain is controlled based on a voltage level of a mode switching signal given from the outside and a voltage level of the signal line.

10. The semiconductor integrated circuit according to claim 7, comprising:
a plurality of the interface blocks,
wherein the test circuit generates a current in accordance with the voltage levels of a plurality of the signal lines corresponding to the interface blocks in the standby mode.

11. The semiconductor integrated circuit according to claim 10, wherein the test circuit has transistor controlled for a current flowing between the source and the drain based on the voltage level of the plurality of signal lines in the standby mode.

12. The semiconductor integrated circuit according to claim 11, wherein the current of the transistor flowing between the source and the drain is controlled based on the voltage level of the mode switching signal given from the outside and the voltage levels of the plurality of signal lines.
